(19) United States
(12) Patent Application Publication
(10) Pub. No.: US 2007/0068571 A1
(43) Pub. Date: Mar. 29, 2007

(54) Shunt Passivation Method for Amorphous Silicon Thin Film Photovoltaic Modules

(75) Inventors: Yuan-Min Li, Monmouth Junction, NJ (US); Zoltan J. Kiss, Monmouth Junction, NJ (US)

Correspondence Address: YUAN-MIN LI, 31 MAIDENHEAD ROAD, PRINCETON, NJ, 08540-7735, US

(73) Assignee: TERRA SOLAR GLOBAL, Monmouth Junction, NJ (US)

(21) Appl. No.: 11/162,977

(22) Filed: Sep. 29, 2005

(51) Int. Cl. H01L 31/00

(52) U.S. Cl. 136/258; 136/261

(57) ABSTRACT

A method for reducing shunt-related defects is described for hydrogenated amorphous silicon (a-Si:H) thin film photovoltaic modules with thin active a-Si:H absorber as required by building integrated photovoltaic windows and sun-roofs with adequate transmission of sunlight. Without shunt-passivation, p-i-n type large area photovoltaic modules with very thin a-Si:H i-layer will suffer excessive performance, yield, and reliability losses due to electrical shorting through i-layer defects. Wide-bandgap a-Si:H based alloy films of sufficient resistivity are deposed between the active solar cell and the conductive back electrode to provide a barrier to leakage current flow. Such a-Si:H based barrier films of high optical transparency are dummy films that do not directly contribute to energy conversion. The shunt-passivation films are entirely produced by the same conventional manufacturing process for a-Si:H photovoltaic devices without invoking complicated or exotic materials or procedures proposed in prior arts.

### BACKGROUND OF THE INVENTION

Due to increasing demands for clean, safe, sustainable, and reliable sources of energy, photovoltaic (PV) systems are undergoing rapid expansion in industrial technology development and in the energy marketplace. Hydrogenated amorphous silicon (a-Si:H) thin films, and the related alloys of hydrogenated amorphous silicon with other elements of various optical bandgaps tailored for various amounts of optical absorption for a given amount of material thickness, have become a relative mature family of PV materials for commercial PV module production that offers low-cost, large area capability, good efficiency, and particularly easy integration with building materials such as windows, roofs, and facades. Due to its relatively wide optical bandgap, a-Si:H is especially well suited to making building integrated PV (BIPV) products, for which the transparency of the BIPV can be controlled, among other things, by the thickness of the a-Si:H layers, particularly their i-layer in an p-i-n type device where ‘i’ refers to the undoped, active light absorber (the ‘intrinsic’ layer). BIPV requires no additional land, making it a good choice in densely-populated areas and urban settings. Also, the added costs of BIPV in building walls, roofs, and windows can be partially offset by the building elements replaced by BIPV components. BIPV also affords easy connection to electric grid (power line coming to the building). Furthermore, semitransparent (or partially transparent, or partially translucent) BIPV windows or ‘skylights’ allows color selection of light entering the living area and enhancements to the architectural appeal of the building. For ease of discussion, we shall use the term “Transparent BIPV Window” to refer to all BIPV windows with some transmission of visible light (>1%).

Glass is a natural and popular choice for BIPV modules since glass is the window material and it offers the chemical stability, durability, and compatibility with a-Si:H PV device processing steps and application environments where BIPV modules must hold up well in various weather conditions over extended periods of time. Thus, glass based a-Si:H BIPV products are very attractive due to their dual functions as energy-generator and architectural components of a building. In glass based a-Si:H BIPV devices, the typical construction comprises a glass substrate (also called superstrate since sun light will impinge on the a-Si:H semiconductor film from the uncoated surface of this glass), a transparent and conductive oxide film as front electrode, a plurality of thin a-Si:H films of different types (usually p-i-n), another TCO such as zinc oxide (ZnO), and normally another metallic film as the back electrode for collecting and carrying photo-electric current. This assembly of films is then laminated with another piece of glass such that all the films are sandwiched between two glass plates for superior protection against the elements for weather-proof, long-lasting installations. The a-Si:H semiconductor layers are responsible for converting light to electrical current (and power). A general a-Si:H solar cell structure is of the p-i-n sequence, where p, i, n respectively refer to the p-type (positively doped), i-type (intrinsic or undoped), and n-type (negatively doped). Boron and phosphorus are popular oats to make p-type and n-type a-Si:H and its alloys such as amorphous silicon-carbon (a-SiC:H) or amorphous silicon-nitrogen (a-SiN:H). The physics of a-Si:H semiconductor dictates that a-Si:H solar cell of optimal efficiency must be of the p-i-n (or n-i-p) device structure, where good devices can be obtained only if the i-layer (made from a-Si:H or a-Si:H alloys with, e.g., germanium or carbon) is sufficiently thick (>50 nanometers or 50 nm), even if there are no defects of any kind. In other words, simple p-n or n-p type of devices will not function as solar cells when a-Si:H based materials are used, in stark contrast to crystalline silicon solar cells that are typically of p-n junction structure. This is due to the very high density of defects in doped a-Si:H alloy thin films. Only photo-generated charge carriers in the i-layer a-Si:H (electrons and holes, representing respectively negative and positive charges) can be separated and extracted for photo-electric energy production. Hence, the thickness of a-Si:H alloy i-layer has a lower-limit threshold, below which the solar cell would have unacceptably low efficiency both because of the device physics flaw and because too little light can be converted to electricity, on the ground that i-layer thickness largely determines the amount of light that can be absorbed and gainfully converted to electrical power.

The majority of a-Si:H PV modules in the marketplace are non-transparent, as either the substrate or the electrodes are opaque metallic materials. Also, for highest power output, a-Si:H i-layers tend to be too thick to allow much light to pass through, particularly in multi-junction solar cells which contain two or three p-i-n structures on top of each other in order to avoid degradation problem associated with single junction a-Si:H cells with thick i-layer. Only single junction solar cells with thin a-Si:H i-layers can be used for truly semi-transparent BIPV modules using the non-film-removal technique which is the main target application of the present invention.

Generally, there are two ways to make glass-encapsulated a-Si:H BIPV modules partially translucent for visible light. Conventionally, partially-transparent BIPV modules are created from non-transparent a-Si:H based PV plates by selectively removing a-Si:H/Al (or a-Si:H/ZnO/Al) using laser ablation technique. The transparency is determined by the amount of ‘open area’ which no longer produces power. The drawback of this ‘destructive’ approach is several folds: slow and costly laser scribing; non-uniform looking pattern; the transparency being proportional to the loss of PV active area (loss of module power). Significant damage to module occurs when ‘dot’ pattern is generated by laser pulses used to blow-away a-Si:H film one spot at a time, leading to excessive power loss. TerraSolar has taken a different approach to producing partially transparent BIPV windows by making all the thin films in the device more transparent to arrive at a non-opaque body without subsequent removal of the films. In particular, the PV active a-Si:H i-layer is made thinner, and the back contact is transparent ZnO (TCO) instead of opaque metal (Al). Such BIPV windows have lower cost, more uniform appearance (without the strong contrast between areas with films and areas without film), more aesthetically pleasing, and higher power output than ‘laser-scribed’ partially-clear modules. Elimination of a-Si:H film in selected area is not needed for light-transmission purpose. Such modules are truly partially-transparent versus the ‘partly transparent’ modules produced by film removal. There are a number of critical processing challenges for see-through, semitransparent a-Si:H BIPV modules for window applications, with thin a-Si:H p-i-n layers and transparent contacts, without removing the films. These technical issues must be addressed to ensure good yield and high performance for BIPV windows of thin a-Si:H i-layer. The foremost technical obstacle is shunting through the very thin a-Si:H i-layer film (<350 nm). Especially for the more transparent windows requiring thinner a-Si:H (e.g., <200 nm), shunting or short-circuit pathways through defects in a-Si:H including pinholes and sharp imperfections in film geometry are largely unavoidable. Notice that even for a-Si:H PV devices with thick a-Si:H i-layers, shunting is a prevalent problem as discussed in the prior arts cited below.

We have developed a shunt-preventive barrier structure involving wide-bandgap a-SiC:H dummy i-layer or a series of dummy i-layers that are not active for photo-electric energy conversion. The shunt-passivation coating, inserted between the active a-Si:H p-i-n structure and the back TCO (transparent conductive oxide) contact, simply serves to provide resistance to leakage current through defects in the active a-Si:H i-layer. The effective ingredient of the barrier coating is the wide-bandgap a-SiX:H thin film (where X can be carbon, oxygen, nitrogen, and/or fluorine) of higher resistivity and higher optical transparency than that of undoped a-Si:H films of the same thickness. This resistive and relatively transparent (wide-bandgap) film can be lightly-doped (n-type), intentionally or unintentionally (due to contamination). Such dummy films can be quite thick (relative to the active a-Si:H i-layer) due to its low optical absorption.

A feature of our BIPV modules is the bi-facial response to light. Because the back contact is transparent and the n-layer is thin, light incident on the ‘back’ of the module can also cause PV action. Our shunt prevention invention can be applied to such bifacial BIPV modules to boost their output power, reliability, and production yield. Such bifacial a-Si:H PV modules are to be used for free-standing outdoor applications and for low-light level indoor use when both sides of the modules are exposed to light. Again, the problem of shunting through thin a-Si:H i-layer is the biggest roadblock to practical production and economic application of such devices. A low-cost, easy-to-implement, fast, effective, robust, and reliable technique to drastically reduce the number of defects in large area a-Si:H PV modules of thin a-Si:H i-layer must be developed in order to realize the potential of a-Si:H based, variably transparent BIPV modules.

Other Solutions and Their Shortcomings

Several solutions have been proposed to address the problem of shunting through semiconductor thin film in a-Si:H based PV devices. Prem Nath and M. Izu in U.S. Pat. No. 4,598,306 (1986) described the inclusion of a continuous, transparent barrier layer operatively deposed between the semiconductor body (a-Si:H film in this case) and one of the electrodes of the PV device. This low-conductivity barrier layer (a continuous film deposited by some suitable means) could substantially restrict the current flow through defective or ‘shunt’ regions. The proposed materials are essentially oxides, nitrides, and carbides of metals and silicon of very wide bandgap for superior transparency. A specific implementation of this concept is disclosed by the same inventors in U.S. Pat. No. 4,532,372 (Nath and lzu, ECD): “The barrier layer is formed from a magnesium fluoride based material.” This “resistive barrier” concept was later further described in U.S. Pat. No. 5,268,039 (Vogeli et al. of United Solar Systems Corp.), which describes a shunt-resistant PV device incorporating a layer of low-conductivity material operatively positioned between the front and back electrodes of the solar cell. Another technique, beneficial specifically to a grid pattern of electrodes, was described in U.S. Pat. No. 4,633,034 (Nath et al. of United Solar Systems Corp.), according to which shunting would be mitigated by the use of a current-flow restricting material below the electrode grid. Generally, the above methods are considered passive or ‘non-destructive’ means for fixing the shunting problem. The present invention represents a great advancement in this type of remedial approach to the inevitable defects in thin film electronic layers over very large areas.

Another class of method to reduce shunting is active passivation in the sense that the deposited thin semiconductor film (in our case a-Si:H i-layer) or the adjacent metallic material is altered or removed in selected areas (the defective regions), not covered up by a continuous low-conduction film. U.S. Pat. No. 4,451,970 (Izu and Cannella, ECD) teaches the art of detecting (locating) the defective regions and eliminating such regions by either removing the conductive electrode layer around such regions or by depositing an insulating film over such regions such that shunt current paths are blocked. In the above patent and in U.S. Pat. No. 4,464,832 (Asick et al.), a method is described to selectively remove conductive film at positions of shunts by immersing the solar cell in an acid, salt, or alkali electrolyte and applying an electrical bias to the solar cell to etch the shunt portion. In U.S. Pat. No. 4,729,970 (Nath and Vogeli, ECD), the short circuit defects are eliminated by converting the electrode (conductive) material to insulating film proximate to the defect regions, using a conversion reagent with suitable activation. The above procedures are elegant and can be very effective, but they are also very elaborate and require sophisticated instrumentation (expensive, high-cost) and a great deal of labor, in addition to the time required that severely limits the throughput for large area PV module production which can have tens of thousands of small defects per square foot of thin film coating.

Yet another invention, U.S. Pat. No. 4,471,036 (Slotheim) describes the elimination of pinholes or porous openings (which become shorts when deposited with electrode) by electrochemical oxidation of selected monomers to deposit insulating polymer in the openings. A similar process was proposed in U.S. Pat. No. 5,277,786 (Kawakami of Canon, Japan), wherein the defective portions of the semiconductor layer are repaired by means of electrolytic treatment using an electrolytic solution containing a material capable of providing an insulating layer to passivate the defective portions. In U.S. Pat. No. 6,132,585 (Midorikawa et al. of Canon), the defective portions of the PV device are selectively covered up by electrodeposited resin (an insulating layer) at the defective regions. These wet processes are time consuming and labor-intensive, in addition to its slow processing speed and special equipment requirements. Also, there is no guarantee that insulating film will not be deposited on non-defective areas of semiconductor thin film.

U.S. Pat. No. 6,716,324 (Yamashita of Canon of Japan) discloses a method to restraining shunting through defective semiconductor layer by avoiding the deposition of conductive film over such defective regions. This is accomplished by controlling the electrical voltages applied to the sputtering target and the substrate during the sputtering deposition of the conductive electrode film. This method is highly questionable since fine, tiny defects in very thin films (which can be very densely and randomly dispersed over large continuous plates or sheets) are unlikely to selectively respond to bias voltages. Only relatively large and extended defects can be detected and perhaps neutralized this way. Also, very sophisticated hardware and software are needed to detect and respond to the presence of small defects during sputtering. This is not a practical solution to the problem addressed by the present invention.

Most of the earlier proposed solutions (prior arts) have shortcomings that are either technically unsound, or impractical in terms of added costs for PV module manufacturing, or aesthetically unappealing for the finished products. All of the prior arts aim for broad coverage of the shunting problem. None of them specifically targets the extreme situation of very thin a-Si:H i-layer needed for truly transparent, non-film-removal BIPV windows. These earlier inventions were not directed at a-Si:H BIPV modules whose transparency can be adjusted by the thickness of a-Si:H i-layer. The necessary thinness of a-Si:H i-layer presents a unique challenge that must be dealt with using custom-tailored solutions. We cannot simply borrow a technique or a combination of techniques stated in prior arts. For instance, the selective electrolyte deposition of highly resistive polymer film at a-Si:H shunting regions (defective regions) cannot be used when a-Si:H i-layer is very thin (e.g., <250 nm), because the deposition of such an insulating layer will not be confined to areas of pinholes or other defects. Instead, due to non-vanishing conductivity of thin a-Si:H, the insulating film will be deposited over the entire a-Si:H film, thus degrading the performance of the a-Si:H p-i-n solar cell. Hence, the shunt-reduced BIPV module will not produce higher output power because of lower collection efficiency of photo-generated electric current despite lower shunting.

Furthermore and just as importantly, none of the prior arts describes a simple method of shunt prevention tightly integrated with the deposition of a-Si:H i-layer, without resorting to additional equipment or additional plate handling, during the production of the shunt-reduced a-Si:H PV modules. The proposed solutions are all too cumbersome and incompatible with traditional a-Si:H PV module manufacturing process flow. In fact, none of the prior arts deals with the electrical leakage of the p-i-n structure by simply making repeated use of the various layers, especially the i-layers that can be made wider-bandgap and insulating, in reducing or passivating defects associated with the thinness of any individual i-layer. This is exactly what is invented by this application. In other words, the present invention directly attacks the shunting problem due to thin a-Si:H i-layer by making the i-layer (or slightly n-type layers) much thicker without actually using the additional thick i-layer (wide-bandgap a-Si:H based alloys) for PV action. Instead, the added i-layers, in the form of n-i-n structure, simply are ‘wasted’ as dummy or sacrificial coating to minimize shunting effect from the active a-Si:H i-layer.

It is therefore an object of the invention to produce semi-transparent amorphous silicon thin film photovoltaic devices of sufficient translucence for building integrated applications such as photovoltaic windows and sky-lights.

It is another object of the invention to produce amorphous silicon photovoltaic devices of thin active undoped hydrogenated amorphous silicon layer (the i-layer) of suitable visible light transmission with low shunting defects, good output power, high yield, and reliable operating characteristics.

It is another object of the invention to prevent or alleviate electrical shunting problem in thin film a-Si:H photovoltaic devices by introducing wider-bandgap hydrogenated amorphous silicon alloy films of adequate electrical resistivity to block electrical shorting paths through the a-Si:H active i-layer in p-i-n type solar cells and large area modules.

### SUMMARY OF THE INVENTION

In accordance with the present invention, there is provided a design for control of shunt defects in semitransparent hydrogenated amorphous silicon (a-Si:H) based p-i-n type thin film photovoltaic (PV) modules of thin i-layer. By inclusion of a dummy film of a-Si:H based alloy material of good translucence and sufficient electrical resistivity between the p-i-n layers and the back electrode, the PV modules will possess lower electrical shunting defects, improved output power, higher product yield, and better reliability than devices without such a shunt-reducing layer. The said a-Si PV modules will permit adequate light transmission, through all the thin film layers, to be suitable for building integrated applications, such as PV windows or sky lights. The light transmission through the PV module does not rely on selected removal of a-Si films or electrodes. Rather, all the thin films in the PV device are individually transparent to a satisfactory degree. In particular, the present invention allows the use of very thin a-Si:H intrinsic layer (the i-layer) in p-i-n type large area PV modules without suffering performance and yield loss due to electrical shorting through defects or insufficient coverage of a-Si:H i-layer between the electrodes. According to this invention, shunt passivation can be effectively and entirely provided by additional, PV-inactive a-Si:H based thin films produced by the same manufacturing process for various a-Si p, i, n layers used in conventional a-Si:H PV module fabrication, without using foreign or exotic procedures or materials. Specifically, p-i-n-“i”-n type device structure is proposed to replace conventional p-i-n device of thin i-layer prone to shunting defects. In the p-i-n-“i”-n configuration, the “i”-layer situated between two n-layers is a dummy layer that serves to passivate shorting defects through the first i-layer which is the active photo-electric component in the solar cell. The shunt blocking dummy layer may comprise multiple a-Si alloy thin films of high electrical resistance and good optical transmission, inter-connected by more conductive, n-type a-Si:H based thin films.

### BRIEF DESCRIPTION OF THE DRAWINGS

FIG. 1 is a section view of an a-Si:H p-i-n type solar cell with two separate but joining i-layers, 50 and 70. The wide-bandgap, insulating a-Si:H alloy film 70 will be used independently as the shunt-passivation layer in later figures disclosed in this invention.

FIG. 2 is shows the layer structure of a semi-transparent a-Si:H based photovoltaic device. The glass-encapsulated a-Si:H p-i-n-“i”-n solar cell contains a thin a-Si:H absorber, or the i-layer 50. Shunt reduction capability is provided by dummy “i” layer 70, while layer 80 is used for making good electrical contact to the back electrode 90. This is the simplest implementation of shunt barrier using a-Si:H based wide-bandgap alloy film deposited by the same method as the conventional a-Si:H based p, i, and n layers in fabricating standard p-i-n devices.

FIG. 3 is a section view of a glass encapsulated a-Si:H p-i-n-SP-n solar cell, where SP (shunt prevention or shunt passivation) layer 70 comprises multiple sub-layers of 71 and 72. Layer 71 is made of thin, wide-bandgap a-Si:H alloys of relatively high resistivity, while 72 denotes n-type, more conductive a-Si:H based thin film of good transparency.

### DETAILED DESCRIPTION OF THE INVENTION

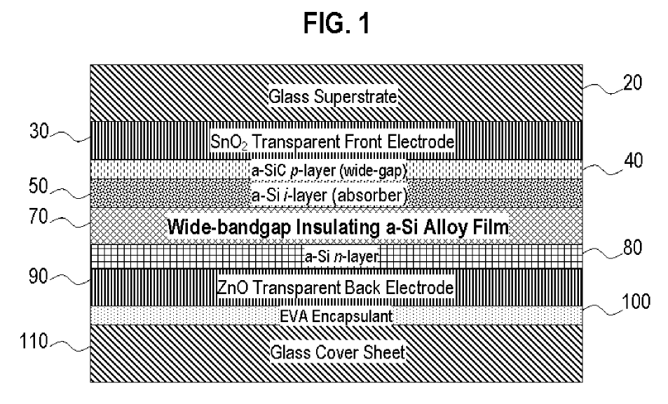

The present invention entails a simple, lower-cost, robust and effective scheme for negating shunting defects in photovoltaic (PV) modules containing a thin hydrogenated amorphous silicon (a-Si:H) active absorber-converter layer appropriate for semi-transparent or see-through PV applications. FIG. 1 shows the cross section of a standard single junction, p-i-n type solar cell encapsulated between two glass plates. The solar cell includes flat glass substrate 20 (also known as superstrate in this type of device configuration), transparent front electrode 30 (transparent conductive oxide or TCO), a-Si:H alloy p-layer 40, a-Si:H i-layer 50 (intrinsic amorphous silicon), a-Si:H n-layer 80, transparent back electrode 90, lamination agent 100 (encapsulation medium), and glass cover plate 110. Also shown in FIG. 1 is an optional a-Si:H based shunt-reducing layer 70, deposed between a-Si:H i-layer 50 and a-Si:H n-layer 80. Without the wide-bandgap, insulating, a-Si:H based shunt-reducing layer 70, the device would be a simple, conventional p-i-n type solar cell without any buffer or extension of the a-Si:H i-layer 50. To make the entire device semitransparent suitable for building integrated photovoltaic (BIPV) window applications, the p-i-n layers (40, 50, and 60) all must be fairly or very thin, with combined thickness less than 400 nanometers (nm), and preferably less than 300 nm. This means that the a-Si:H i-layer 50 thickness should be less than 350 nm, and preferably less than 250 nm. Shorting or shunt defects are unavoidable for solar cells containing so thin an i-layer, especially over large areas (e.g., near one square-meter in size). With layer 70 included, the p-i-i-n device incorporates a buffer or alloy film 70 to render the device much less prone to shunting because of increased thickness of total i-layer and higher electrical resistance. Thus, the addition of i-layer 70 of wider bandgap and higher resistivity, to a-Si:H i-layer 50, can reduce shunting or shorting by simply increasing the thickness of the i-layer and increasing the resistance to the flow of leakage current through the combined i-layer stack. When film 70 is made of wider bandgap a-Si:H alloys, such as hydrogenated amorphous silicon-carbon alloy (a-SiC:H) of larger than 1.9 eV optical bandgap, even a fairly thick film (>150 nm) can be added to the solar cell with little further loss in the transmission of visible light. However, in practice, this approach to overcoming shunting will not work for two reasons. The first reason is the poor stability of wide-bandgap a-Si:H alloys such as a-SiC:H, which will rapidly and severely degrade upon exposure to light. The second reason is that wide-bandgap a-Si:H alloy i-layers are of low electronic quality, and thick layers of undoped a-SiC:H or other alloys will significantly reduce the power output of the photovoltaic device (even before light-induced degradation becomes evident) due to high density of electronic defects. Thus, simply adding layer 70 to the standard i-layer 50, as sown in FIG. 1, will not be an effective or long-lasting solution to shunting problem associated with thin a-Si:H i-layer 50.

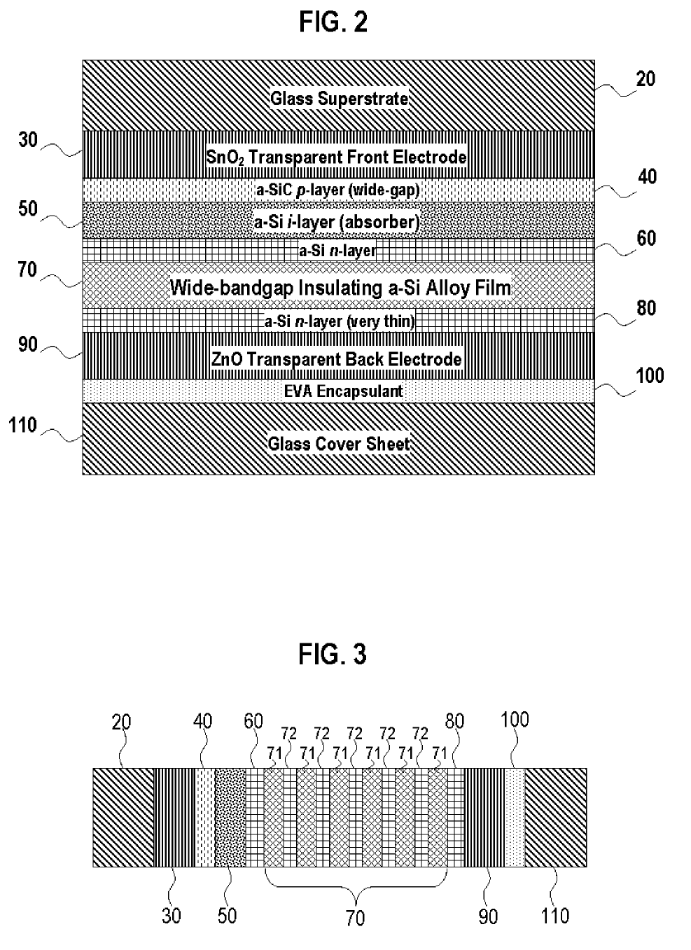

The present invention is illustrated in FIG. 2, which is a cross-section view of a glass-encapsulated a-Si:H solar cell, based on the p-i-n structure but modified to include two additional layers compared to FIG. 1. The only change in device structure is the inclusion of another a-Si:H based n-layer 60 (besides n-layer 80 which is in contact with back electrode layer 90), between a-Si:H i-layer 50 and wider-bandgap a-Si:H based shunt-reducing layer 70. In this p-i-n-i-n device structure (40-50-60-70-80), layer 70 and layer 80 form a two-layer blocking structure to act as a barrier against electrical shunts associated with defects or imperfections of any kind in a-Si:H i-layer 50. The functional component for shunt passivation is layer 70, while the function of layer 80 is simply to provide good electrical contact to the transparent back electrode 90. This p-i-n-i-n device configuration, with insulating and transparent a-Si:H alloy i-layer or lightly doped film 70 between the two n-type a-Si:H based films 60 and 80, is the heart of the present invention.

When transparent conductive oxide such as ZnO is used as transparent back electrode 90 (conventionally called back contact for p-i-n type solar cells when light impinges on the solar cell from the side of the flat glass substrate 20), and all the a-Si:H based thin film elements 40, 50, 60, 70, and 80 are all at least somewhat transparent, a semi-transparent solar cell is obtained. Such partially-translucent solar cells are also bi-facial, responding to light from either front glass side or back glass side. Semitransparent BIPV modules and/or bifacial BIPV modules are obtained by uniformly depositing all the layers over large areas. Bifacial PV module simply refers to PV module which can produce electric power from light impinging on the module from either side (front glass or back cover glass), in contrast to the conventional PV modules which are designed to function in a particular direction of incident light (from the side of the outer surface of the superstrate).

Note the difference in device operations between FIG. 1 and FIG. 2. The a-Si:H based shunt-reducing layer 70 is a ‘dummy’ layer in FIG. 2 because it is positioned between two n-type a-Si:H based films. The n-i-n structure does not produce any photovoltaic effect. It however will provide electrical resistance in the direction perpendicular to the multi-layer device structure. As a result, low electronic quality and poor stability of the a-Si:H based shunt-reducing layer 70 in the n-i-n structure does not affect the performance of the photovoltaic device embodied by the p-i-n layers (40, 50, and 60). In other words, as far as photo-electric power generation is concerned, the electronic quality of layer 70 does not matter (or matters very little). According to the present invention, the a-Si:H based shunt-reducing layer 70 is an a-Si:H based wide-bandgap alloy film that satisfies all three of the following requirements simultaneously. 1) It can be deposited by the same method, preferably in the same a-Si:H deposition machine, as the preceding p-i-n a-Si:H films, represented by layers 40, 50, and 60, respectively. For instance, if the p, i, and n layers (40, 50, and 60) are produced by plasma enhanced chemical vapor deposition (PECVD) technique using a batch reactor, then layers 70 and 80 should be able to be grown by PECVD in the same film-forming PECVD apparatus. 2) Layer 70 is comparatively transparent to visible light, with a red-light transmission value of greater than 10% when measured as a stand-alone film. Thus, the film thickness and optical bandgap must be chosen properly. 3) Layer 70 must be sufficiently resistive to meaningfully restrict electrical current flow through defect regions (“shorts”) across the a-Si:H i-layer 50. Additionally, layer 70 must be stable in these properties. The electrical resistivity (which is the inverse of conductivity) should be comparable to, or only slightly less than, that of undoped a-Si:H film, in the nano-Ohm.cm (10⁻⁹ Ohm.cm) range. Undoped or very lightly doped films of wide-bandgap a-Si:H alloy films, such as hydrogenated amorphous silicon-carbon (a-SiC:H or simply a-SiC), hydrogenated amorphous silicon-oxygen (a-SiO:H), hydrogenated amorphous silicon-nitrogen (a-SiN:H), or fluorinated-hydrogenated amorphous silicon (a-SiF:H), can satisfy the above requirements. The above alloying elements to a-Si:H (carbon, oxygen, nitrogen, and fluorine) all serve to broaden the optical bandgap (to provide higher light transmission) and increase the electrical resistivity of the a-Si:H film (in the absence of doping, or with the same amount of doping). All these alloy films can be readily produced in the same way as a-Si:H based p, i, n layers used in the simple p-i-n solar cells. For instance, by adding methane (CH₄) to a feed gas mixture of silane (SiH₄) and hydrogen (H₂) flowing into the PECVD system, a-SiC:H film can be grown. The bandgap of the film depends on such variables as plasma conditions and methane to silane gas ratio. Thickness and bandgap together determine the optical transmission of such a film. The resistivity of such a film is determined by the bandgap and doping level (including non-intentional doping or contamination). Since layer 70 only needs to be of low optical absorption and to be reasonably insulating to significantly impede the flow of leakage current through defect regions of layer 50, it can contain high density of electronic defects and still function properly for our purpose. As a result, wide-bandgap alloys of a-Si:H including a-SiC:H, a-SiO:H, a-SiN:H, a-SiF:H, and their alloys (e.g., a-SiCO:H), either undoped or lightly doped, are ideally suited as the materials for a-Si:H based shunt-reducing layer 70. These films can all be conveniently and reliably deposited in the same thin film deposition apparatus conventionally deployed for growing all the a-Si:H films in the fabrication of large area, semitransparent a-Si:H BIPV modules. In manufacturing operation, devices with shunt-reduction feature as described in this invention can be processed the same way as conventional p-i-n type PV modules, except that two additional a-Si:H based thin films (or several sets of such films as described later) are added to the process. There is only slight decrease in production throughput, and minimal additional costs to production equipment. The layers 70 and 80 in FIG. 2 do not contribute to conversion of light into electrical power. That is, the second i-layer in the p-i-n-i-n solar cell (layer 70) is a dummy, non-active i-layer as far as solar-electric energy conversion efficiency is concerned. Only the first i-layer 50, sandwiched between the p-layer 40 and the first a-Si:H based n-layer 60, plays the direct role of converting absorbed light to electric power. This unique device structure, absent in conventional solar cells including thin film a-Si:H based p-i-n or n-i-p PV devices, is the foundation of shunt-passivation mechanism disclosed in the present invention. The increase in tolerance to shorting or shunting defects, which are often extremely severe for thin a-Si:H i-layer 50 over large areas in a commercial production environment, is accomplished by the insertion of layer 70 between layer 60 and 80. The presence of 70 provides resistance to current flow between the two electrodes represented by layer 30 and 90. When defects such as pinholes, incorporated particulates, ultra-thin film coverage, or sharp protrusions are common, particularly for semitransparent a-Si:H solar cells of thinner a-Si:H i-layer 50 due to light-transmission requirement, the presence of a moderately thick dummy insulating layer 70, in many ways equivalent to making layer 50 thicker (as depicted in FIG. 1), blocks leakage paths for electrical current which would otherwise exist between the front and back electrodes to severely degrade the performance of the solar cell. An equivalent way to look at the device structure of FIG. 2 is to divide the original p-i-n solar cells in FIG. 1 into two parts, by splitting the i-layer into two, such that only the first i-layer is active, and the second i-layer is ‘dead’ due to absence of p-type film on either side. The ‘dead’ i-layer (70) can be made thick if it has wide enough optical bandgap that permits adequate passage of light through the film for BIPV applications. In FIG. 2, layer 70 is deliberately sandwiched between two n-type, a-Si:H based films (layer 60 and 80) to create the n-i-n sequence. As stated earlier, layer 70 does not have to be undoped (i-layer). Rather, layer 70 can be doped according to its bandgap to attain the necessary resistivity which is appropriate to device operation. In other words, layer 70 can be neither too insulating nor much more conductive than that of undoped a-Si:H film of the same thickness. If very high bandgap (greater than 2.0 eV) a-Si:H alloys are used for layer 70, then even high doping level (e.g., >1% of PH₃ relative to SiH₄ in the supply gas mixture for plasma deposition) may be used without resulting in conductive film. Normally, the wider the bandgap, the more difficult it is to dope a-Si:H alloy films. Hence, in our description, layer 70 is sometimes called ‘undoped’ a-Si:H or i-layer simply for convenience. In practice, layer 70 can be lightly, moderately or substantially doped by such elements as phosphorus or gallium to change its electrical resistivity, as needed, to achieve overall optimal performance for the shunt-passivated PV module.

The overall solar cell structure, p-i-n-i-n shown in FIG. 2 is equivalent to the conventional p-i-n type in terms of conversion efficiency, as long as the last i-n dual-layer (70 and 80) does not severely limit the normal flow of photo-current generated by the first a-Si:H i-layer 50. We have verified experimentally that if the a-Si:H based shunt-reducing layer 70 is made of undoped a-Si:H, or a-SiC:H of small thickness (<100 nm), the added i-n layers (70 and 80) do not appreciably affect the conversion efficiency of large-area, glass-substrate based, a-Si:H p-i-n type PV modules. However, if layer 70 is too insulating (depending on its bandgap, doping level, and thickness), the p-i-n-i-n solar cell will suffer loss in photo-electric power conversion compared to the basic p-i-n device (without considering shunting effect). A good balance must be struck between the efficacy of the shunt-passivation structure and the impact of added series resistance on the performance of the PV module. If layer 70 is too resistive, the photovoltaic energy conversion efficiency of the module will suffer.

In practice, to make BIPV windows more transparent, a-Si:H i-layer 50 needs to be made thinner which leads to more severe shunting. Consequently, a-Si:H based shunt-reducing layer 70 must be made thicker to increase its shunt-blocking ability. But we have argued that if layer 70 is too thick for a given level of resistivity, the p-i-n-i-n device will lose its energy conversion efficiency due to resistive loss through the 2nd i-layer (70) in FIG. 2. To solve this problem, we can modify the i-n (70-80) shunt-blocking structure by using a series of thinner i-n dual-layers, instead of one thick layer 70. This concept is illustrated in FIG. 3, which is a cross-section view of a glass encapsulated a-Si:H p-i-n-i-n type solar cell containing multiple layers of wide-bandgap a-Si:H alloys for shunt reduction.

FIG. 3 is substantially similar to FIG. 2, except the single a-Si:H based shunt-reducing layer 70 in FIG. 2 is now replaced by a series of thinner, resistive wide-bandgap a-Si:H alloy films 71 interconnected by n-type wide-bandgap a-Si:H alloy thin films 72. In this implementation, the shunt-passivation element #70 consists of a plurality of sub-elements 71 and 72, in alternating sequence (71-72-71-72 . . . ). In other words, in FIG. 3, the a-Si:H based shunt-reducing element comprises alternating layers of 71 and 72, in the i-n-i-n-i-n sequence, where i refers to sub-layer film of high resistivity and wide-bandgap, and n refers to sub-layer film of moderately low resistivity and good optical transparency. To maximize the effect of electrically blocking shunting paths while minimizing optical loss, layers 72 should be as thin as possible. The effectiveness of shunt-reduction by this multiple stack structure (71-72-71-72 . . . ) in FIG. 3 will depend on the total thickness of all the layers 71, and their electrical resistivity. FIG. 3 is an alternative embodiment of the same concept depicted in FIG. 2 for shunt suppression for a-Si:H PV devices of thin absorber layer 50. The device structure of FIG. 3 is more complicated than that of FIG. 2. But the collection of thin films 71, instead of a single thick film of 70 in FIG. 2, allows the total thickness of the insulating films (the sum of all layers denoted as 71 in FIG. 3) to far exceed that of film 70 in FIG. 2 for much stronger passivation of shunts in a-Si:H solar cells of thin a-Si:H i-layer 50, without causing significant degradation of solar cell conversion efficiency. The physical reason is that when insulating films (71) are sufficiently thin and sandwiched between moderately conductive layers (72), photocurrent can readily tunnel through the insulating thin films without suffering excessive resistive loss. At the same time, the shunting paths are effectively blocked by the many insulating films. Thus, FIG. 3 is an improvement over FIG. 2 in terms of reducing the negative impact of shunt-reducing films on the energy conversion efficiency of the native photovoltaic devices (comprising layers 40, 50, and 60). The number of layers of 71 (and 72) can be determined by the requirements on the BIPV device such as the exact thickness of i-layer 50, and the degree of resistivity of each layer 71. Further, the layers labeled as 71 (and 72) in FIG. 3 do not have to be identical, as they can have different optical and electrical bandgaps, resistivity, and thickness. In fact, each layer can be non-uniform (e.g., with graded bandgap or varied doping level). Here we only describe a general scheme for shunt-passivation in a-Si:H based PV modules of thin a-Si:H active layer (absorber layer 50 which does not include non-active layer), not the detailed implementations of the concept. Indeed, there are numerous ways to achieve the same objective using this invention.

What is claimed is:

1. A shunt passivation method for amorphous silicon thin film photovoltaic modules for improving yield, output power, and reliability of a-Si:H photovoltaic devices containing thin a-Si:H i-layer (the ‘absorber’), particularly somewhat-transparent building integrated photovoltaic (BIPV) products, comprising:
means for providing support and protection, and serving as a carrier, for subsequently deposited thin films of the partially transparent BIPV device;
means for providing electrical contact (the front electrode) using transparent and conductive oxide, such as tin oxide (SnO₂), on the light-impinging side of the p-i-n type a-Si:H based solar cell, rigidly attached to said means for providing support and protection, and serving as a carrier, for subsequently deposited thin films of the partially transparent BIPV devices;
means for providing p-type electronic potential and junction formation for a-Si:H based p-i-n type solar cell by depositing a wide-bandgap a-Si:H alloy based p-layer, which is normally made of a-SiC:H (hydrogenated amorphous silicon carbide) or a-SiO:H (hydrogenated amorphous silicon oxide) alloys with boron doping, rigidly bonded to said means for the transparent front electrode;
means for serving as the active light absorber or i-layer for p-i-n solar cell using thin hydrogenated amorphous silicon (a-Si:H) films which directly converts absorbed light to electrical power, rigidly interconnected to said p-layer;
means for serving as the n-layer and providing junction action for p-i-n type solar cell by depositing phosphorus-doped a-Si:H based n-layer, which can be a-Si:H or wide-bandgap a-Si:H based alloys, such as a-SiC:H or a-SiO:H, rigidly interconnected to said light absorber or the i-layer;
means for providing shunt reduction by increasing electrical resistance to current flow across the front and back contacts (elements #30 & #90). The wide-bandgap, transparent and relatively resistive a-Si:H based alloy film, or the shunt passivation layer, which is the essential element of the invention, is rigidly attached to said a-Si:H based n-layer; The sole function of the shunt reduction layer is to block the flow of leakage or shunt current which would otherwise exist and which would degrade the performance of the PV device;
means for providing a low-resistivity electrical contact layer 80 to the shunt passivation layer (shunt prevention layer) and particularly to the back electrode layer 90 when used in this invention. This a-Si:H based n-type film is deposited with moderate to heavy phosphorus-doping, is rigidly attached to said shunt passivation layer;
means for serving as light-passing back electrode to the semitransparent solar cell, typically using transparent conductive oxide (TCO) film such as zinc oxide (ZnO), securely bonded to said low-resistivity electrical contact layer (80) to provide good electrical connection to the back side of the said device;
means for providing bonding action to cover glass (#110) and acting as encapsulation (sealer) for the various a-Si:H layers and electrode films, rigidly bonded to said back electrode;
means for providing encapsulation, strength, and physical protection to the solar cell, especially large area PV module, rigidly bonded to said means for providing bonding action to cover glass (#110) and acting as encapsulation (sealer) for the various a-Si:H layers and electrode films, and adhesively adhered to said means for providing support and protection, and serving as a carrier, for deposited thin films of the partially transparent BIPV device;
means for providing uniform and electrically resistive coverage over the entire substrate for passivation of the a-Si:H p-i-n solar cell without directly contributing to light conversion into electricity (in contrast to the prior-deposited i-layer in the p-i-n sequence), structurally incorporated into said means for providing shunt reduction by increasing electrical resistance to current flow across the front and back contacts (elements #30 & #90). This wide-bandgap transparent and relatively resistive a-Si:H alloy film is the essential element of the invention; and
means for working in conjunction with the resistive element 71 such that electrical current of the solar cell can go through the passivation structure consisting of multiple stacks of 71 and 72 without suffering resistive loss which would otherwise occur by using element 71 alone. The thin film 72 is of moderate electrical conductivity, which is much higher than that of layer 71, rigidly connected to said means for providing uniform and electrically resistive coverage over the entire substrate for passivation of the a-Si:H p-i-n solar cell without directly contributing to light conversion into electricity (in contrast to the prior-deposited i-layer in the p-i-n sequence), and rigidly bonded to said means for providing shunt reduction by increasing electrical resistance to current flow across the front and back contacts. The plurality of wide-bandgap transparent and relatively resistive a-Si:H alloy films is the essential element of the invention.

2. The shunt passivation method for amorphous silicon thin film photovoltaic modules in accordance with claim 1, wherein said means for providing support and protection, and serving as a carrier, for subsequently deposited thin films of the partially transparent BIPV device comprises a flat glass substrate.

3. The shunt passivation method for amorphous silicon thin film photovoltaic modules in accordance with claim 1, wherein said means for the transparent and conductive oxide (TCO), acting as the electrical contact (the front electrode) on the light-impinging side of the p-i-n type a-Si:H based solar cell comprises a tin oxide (SnO₂) thin film or ZnO thin film of various surface morphology (granular texture) formed by any means.

4. The shunt passivation method for amorphous silicon thin film photovoltaic modules in accordance with claim 1, wherein said means for providing p-type electronic potential and junction formation for a-Si:H based p-i-n type solar cell is provided by wide-bandgap a-Si:H alloy based p-layer, which is normally made of a-SiC:H or a-SiO:H with boron doping.

5. The shunt passivation method for amorphous silicon thin film photovoltaic modules in accordance with claim 1, wherein said means for serving as the active light absorber for p-i-n solar cell using thin hydrogenated amorphous silicon (a-Si:H) films comprises a thin film of undoped (intrinsic) a-Si:H absorber layer (the so-called i-layer in p-i-n type solar cells).

6. The shunt passivation method for amorphous silicon thin film photovoltaic modules in accordance with claim 1, wherein said means for serving as the n-layer and providing junction action for p-i-n type solar cell action comprises a phosphorus-doped a-Si:H based n-layer made from either a-Si:H or wide-bandgap a-Si:H based alloys, such as a-SiC:H or a-SiO:H, doped with appropriate amounts of phosphorus.

7. The shunt passivation method for amorphous silicon thin film photovoltaic modules in accordance with claim 1, wherein said means for providing shunt reduction by increasing electrical resistance to current flow across the front and back contacts (elements #30 & #90) comprises an a-Si:H based shunt-reducing layer (or the shunt passivation layer). The said layer is a wide-bandgap, partially transparent and relatively resistive a-Si:H alloy film or stack of films (70 or multiple 71-72 bi-layers).

8. The shunt passivation method for amorphous silicon thin film photovoltaic modules in accordance with claim 1, wherein said means for acting as either an n-layer for p-i-n a-Si:H solar cells, or as low-resistivity electrical contact layer to the shunt passivation layer and particularly to the back electrode layer (#90) when used in this invention, comprises an a-Si:H based n-type film deposited with moderate to heavy phosphorus-doping.

9. The shunt passivation method for amorphous silicon thin film photovoltaic modules in accordance with claim 1, wherein said means for serving as light-passing back electrode to the semitransparent solar cell comprises typically of transparent conductive oxide (TCO) films such as zinc oxide (ZnO).

10. The shunt passivation method for amorphous silicon thin film photovoltaic modules in accordance with claim 1, wherein said means for providing bonding action to cover glass (#110) and acting as encapsulation (sealer) for the various a-Si:H layers and electrode films comprises a lamination agent such as ethylene vinyl acetate (EVA).

11. The shunt passivation method for amorphous silicon thin film photovoltaic modules in accordance with claim 1, wherein said means for providing encapsulation, strength, and physical protection to the solar cell, especially large area PV module comprises a glass cover plate (the back plate).

12. The shunt passivation method for amorphous silicon thin film photovoltaic modules in accordance with claim 1, wherein said means for providing uniform and electrically resistive coverage over the entire substrate for passivation of the a-Si:H p-i-n solar cell without directly contributing to light conversion into electricity (in contrast to the prior-deposited i-layer in the p-i-n sequence) comprises a resistive wide-bandgap a-Si:H alloy film.

13. The shunt passivation method for amorphous silicon thin film photovoltaic modules in accordance with claim 1, wherein said means for working in conjunction with the resistive element 71 such that photo-electric current of the solar cell can go through the passivation structure consisting of multiple stacks or bi-layers of 71 and 72 without suffering resistive loss which would otherwise occur by using element 71 alone. The thin film 72 which is of moderate electrical conductivity much higher than that of layer 71 comprises a n-type wide-bandgap a-Si:H alloy thin film.

14. A shunt passivation method for amorphous silicon thin film photovoltaic modules for improving yield, output power, and reliability of a-Si:H photovoltaic devices containing thin a-Si:H i-layer, particularly somewhat-transparent building integrated photovoltaic (BIPV) products, comprising:
a flat glass substrate, for providing support and protection, and serving as a carrier, for subsequently deposited thin films of the partially transparent BIPV device;
a transparent front electrode, comprising transparent and conductive oxide (TCO), such as tin oxide (SnO₂), acting as the electrical contact on the light-impinging side of the p-i-n type a-Si:H based solar cell, rigidly attached to said Flat Glass Substrate;
an a-Si:H alloy p-layer, for providing p-type electronic potential and junction formation for a-Si:H based p-i-n type solar cell. The wide-bandgap a-Si:H alloy based p-layer is normally made of a-SiC:H or a-SiO:H with boron doping, rigidly bonded to said Transparent Front Electrode;
an a-Si:H i-layer, for serving as the active light absorber for p-i-n solar cell using thin hydrogenated amorphous silicon (a-Si:H) films, rigidly interconnected to said a-Si:H alloy based p-layer;
an a-Si:H based n-layer, for serving as the n-layer and providing junction action for p-i-n type solar cell action. The phosphorus-doped a-Si:H based n-layer for a-Si:H solar cell can be made from wide-bandgap a-Si:H alloys, such as a-SiC:H or a-SiO:H, rigidly interconnected to said a-Si:H i-layer;
an a-Si:H based shunt-reducing layer, for providing shunt reduction by increasing electrical resistance to current flow across the front and back contacts. This wide-bandgap, transparent and relatively resistive a-Si:H alloy film is the essential element of the invention, rigidly attached to said a-Si:H based n-layer;
an a-Si:H n-layer, for acting as the n-layer for p-i-n a-Si:H solar cells, or as the low-resistivity electrical contact layer to the shunt prevention layer and particularly to the back electrode layer (#90) when used in this invention. This a-Si:H based n-type film 80 is deposited with moderate to heavy phosphorus-doping, specifically joined to said a-Si:H Based Shunt-Reducing Layer;
a transparent back electrode, for serving as light-passing back electrode to the semitransparent solar cell, typically using transparent conductive oxide (TCO) film such as zinc oxide (ZnO), securely bonded and electrically-coupled to said a-Si:H Based n-Layer 80;
a lamination agent, for providing bonding action to cover glass (#110) and acting as encapsulation (sealer) for the various a-Si:H layers and electrode films, rigidly bonded to said Transparent Back Electrode;
a glass cover plate, for providing encapsulation, strength, and physical protection to the solar cell, especially large area PV module, rigidly bonded to said Lamination Agent, and adhesively adhered to said Flat Glass Substrate;
a resistive wide-bandgap a-Si:H alloy film, for providing uniform and electrically resistive coverage over the entire substrate for passivation of the a-Si:H p-i-n solar cell without directly contributing to light conversion into electricity, structurally forming a part of said a-Si:H Based Shunt-Reducing Layer; and
an n-type wide-bandgap a-Si:H alloy thin film 72, for working in conjunction with the resistive element 71 such that photo-electric current of the solar cell can go through the passivation structure consisting of multiple stacks of 71 and 72 without suffering resistive loss which would otherwise occur by using element 71 alone. Thin film 72 is of moderate electrical conductivity, which is much higher than that of layer 71. The plurality of thin films (71 and 72), rigidly connected to previously formed films, structurally forms said a-Si:H Based Shunt-Reducing Layer (the shunt passivation layer).

15. A shunt passivation method for amorphous silicon thin film photovoltaic modules for improving yield, output power, and reliability of a-Si:H photovoltaic devices containing thin a-Si:H i-layer, particularly somewhat-transparent building integrated photovoltaic products, comprising:
a flat glass substrate, for providing support and protection, and serving as a carrier, for subsequently deposited thin films of the partially transparent BIPV device;
a transparent front electrode, comprising transparent and conductive oxide (TCO) such as tin oxide (SnO₂), and acting as the electrical contact (the front electrode) on the light-impinging side of the p-i-n type a-Si:H based solar cell and rigidly attached to said Flat Glass Substrate;
an a-Si:H alloy p-layer, for providing p-type electronic potential and junction formation for a-Si:H based p-i-n type solar cell. The wide-bandgap a-Si:H alloy based p-layer is normally made of a-SiC:H or a-SiO:H with boron doping, rigidly bonded to said Transparent Front Electrode;
an a-Si:H i-layer, for serving as the active light absorber for p-i-n solar cell using thin a-Si:H films, rigidly interconnected to said a-Si:H Alloy p-Layer;
an a-Si:H based n-layer, for serving as the n-layer and providing junction action for p-i-n type solar cell. The phosphorus-doped a-Si:H based n-layer for a-Si:H solar cell can be made from wide-bandgap a-Si:H alloys, such as a-SiC:H or a-SiO:H, rigidly interconnected to said a-Si:H i-Layer;
an a-Si:H based shunt-reducing layer (shunt passivation layer), for providing shunt reduction by increasing electrical resistance to current flow across the front and back contacts. This wide-bandgap transparent and relatively resistive a-Si:H alloy film is rigidly attached to said a-Si:H based n-layer;
an additional a-Si:H n-layer or a-Si:H alloy n-layer, inserted between the Shunt Passivation Layer and the Transparent Back Electrode, for acting as low-resistivity electrical contact layer to the shunt prevention layer and particularly to the back electrode layer. This a-Si:H alloy based n-type film 80 is deposited with moderate to heavy phosphorus-doping, specifically joined to said a-Si:H Based Shunt-Reducing Layer (Shunt Passivation Layer);
a transparent back electrode, for serving as light-passing back electrode to the semitransparent solar cell, typically using transparent conductive oxide (TCO) film such as zinc oxide (ZnO), securely bonded to said a-Si:H alloy based n-Layer deposed on the Shunt Passivation Layer;
a lamination agent, for providing bonding action to cover glass 110 and acting as encapsulation (sealer) for the various a-Si:H based layers and electrode films, rigidly bonded to said Transparent Back Electrode;
a glass cover plate, for providing encapsulation, strength, and physical protection to the solar cell, especially large area PV module, rigidly bonded to said Lamination Agent, and adhesively adhered to said Flat Glass Substrate;
a resistive wide-bandgap a-Si:H alloy film, for providing uniform and electrically resistive coverage over the entire substrate for passivation of the a-Si:H p-i-n solar cell without directly contributing to light conversion into electricity, structurally attached to a-Si:H n-layer 60 and forming part of a-Si:H Based Shunt-Reducing Layer; and
an n-type wide-bandgap a-Si:H alloy thin film, for working in conjunction with the resistive element 71 such that photo-electric current of the solar cell can go through the passivation structure consisting of multiple stacks of 71 and 72 without suffering resistive loss which would otherwise occur by using element 71 alone. Thin film 72 is of moderate electrical conductivity, which is much higher than that of Resistive Wide-bandgap a-Si:H Alloy Film 71, rigidly connected to 71 to form said a-Si:H Based Shunt-Reducing Layer.
